(19) United States
(12) Patent Application Publication
(10) Pub. No.: US 2025/0089275 A1
(43) Pub. Date: Mar. 13, 2025

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Hui-Hung Shen, New Taipei City (TW); Ke-Jing Yu, Kaohsiung City (TW); Yu-Chen Chang, Taoyuan City (TW); Anhao Cheng, Taichung City (TW); Yen-Liang Lin, Tainan City (TW); Ru-Shang Hsiao, Jhubei City (TW)

(21) Appl. No.: 18/401,746

(22) Filed: Jan. 2, 2024

Related U.S. Application Data
(60) Provisional application No. 63/581,721, filed on Sep. 11, 2023.

(51) Int. Cl. H01L 29/94; H01L 27/06; H01L 29/66

(52) U.S. Cl. CPC H10D 1/66; H10D 1/047; H10D 84/811

(57) ABSTRACT

A semiconductor device and method of manufacturing the same are provided. The semiconductor device includes a substrate and a capacitor structure. The capacitor structure is disposed on the substrate. The capacitor structure includes a first electrode and a plurality of second electrodes. At least one of the plurality of second electrodes is embedded within the first electrode.

### REFERENCE TO RELATED APPLICATION

This application claims the benefit of U.S. Provisional Application No. 63/581,721, filed on Sep. 11, 2023, the contents of which are hereby incorporated by reference in their entirety.

### BACKGROUND

Technological evolution of integrated circuit (IC) materials and design has resulted in smaller and more complex circuits each generation. In the course of such IC evolution, functional density (e.g., the number of interconnected devices per chip area) has generally increased while geometric size (e.g., the smallest component (or line) that may be created using a fabrication process) has decreased. This scaling down provides benefits of increased production efficiency and lower associated costs.

The noted scaling down has further increased the complexity of IC manufacture, such that for the advances to be fully realized, corresponding developments in IC manufacture are needed.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A illustrates a top view of a semiconductor device, in accordance with some embodiments of the present disclosure.

FIG. 1B illustrates a cross-sectional view along line A-A′ of the semiconductor device as shown in FIG. 1A, in accordance with some embodiments of the present disclosure.

FIG. 1C illustrates a partial enlarged view of the semiconductor device as shown in FIG. 1B, in accordance with some embodiments of the present disclosure.

FIG. 2A, FIG. 2B, FIG. 2C, FIG. 2D, FIG. 2E, FIG. 2F, FIG. 2G, FIG. 2H, FIG. 2I, and FIG. 2J illustrate various stages of manufacturing a semiconductor device, in accordance with some embodiments of the present disclosure.

FIG. 3 illustrates a cross-sectional view of a semiconductor device, in accordance with some embodiments of the present disclosure.

FIG. 4 illustrates a cross-sectional view of a semiconductor device, in accordance with some embodiments of the present disclosure.

FIG. 5 illustrates a cross-sectional view of a semiconductor device, in accordance with some embodiments of the present disclosure.

FIG. 6A, FIG. 6B, FIG. 6C, FIG. 6D, and FIG. 6E illustrate various stages of manufacturing a semiconductor device, in accordance with some embodiments of the present disclosure.

FIG. 7 is a flowchart of a method for manufacturing a semiconductor device according to various aspects of the present disclosure.

FIG. 8 is a flowchart of a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain error necessarily resulting from the standard deviation found in the respective testing measurements. Also, as used herein, the terms “substantially,” “approximately” and “about” generally mean within a value or range that can be contemplated by persons having ordinary skill in the art. Alternatively, the terms “substantially,” “approximately” and “about” mean within an acceptable standard error of the mean when considered by one of ordinary skill in the art. Persons having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure is related to semiconductor devices and fabrication methods. More particularly, the present disclosure is related to a semiconductor device including a capacitor structure. The capacitor structure includes a first electrode (e.g., upper electrode) and multiple second electrodes (e.g., lower electrodes), some of which are embedded within the first electrode. As a result, the capacitance of the capacitor structure is enhanced. Further, the processes of manufacturing said capacitor structure can be integrated with those of manufacturing logic device(s), which simplifies the steps of the processes. Said capacitor structure can, for example, function as a filter to remove unnecessary signals.

A semiconductor device including planar transistors and the methods of manufacturing the same are provided in accordance with various exemplary embodiments. The intermediate stages of forming the transistors are illustrated in accordance with some embodiments. Some variations of some embodiments are discussed. For example, gate-all-around (GAA) transistors or fin field-effect transistors (FinFETs) may also adopt the embodiments of the present disclosure.

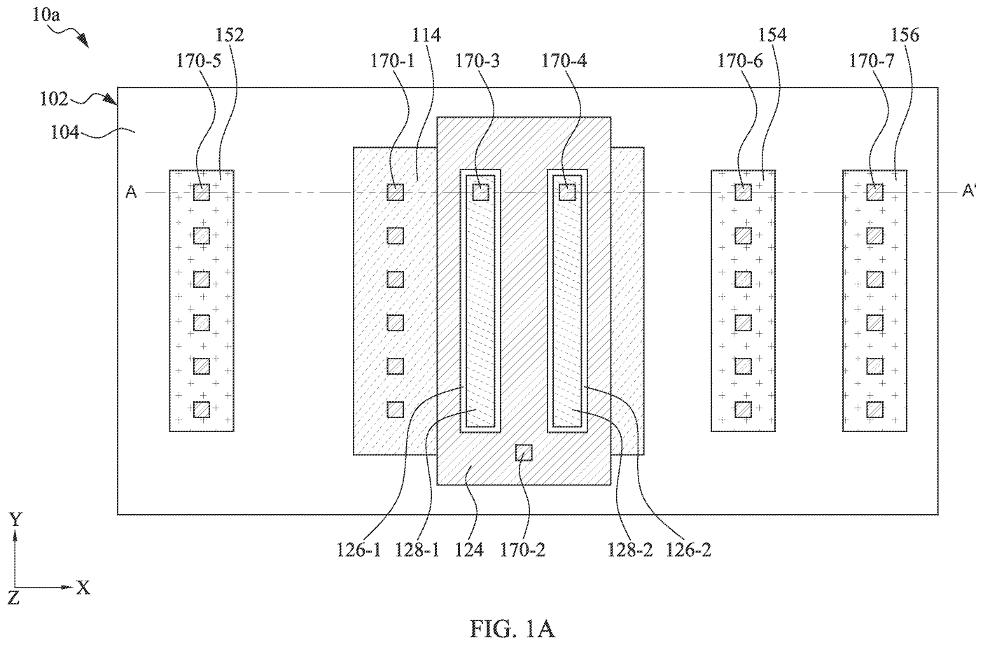

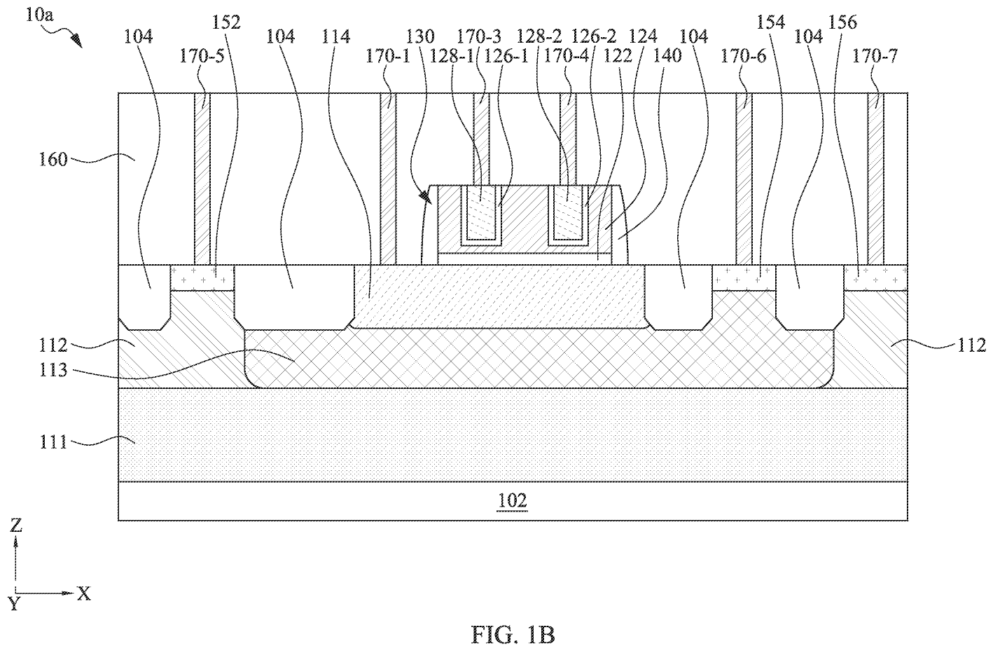

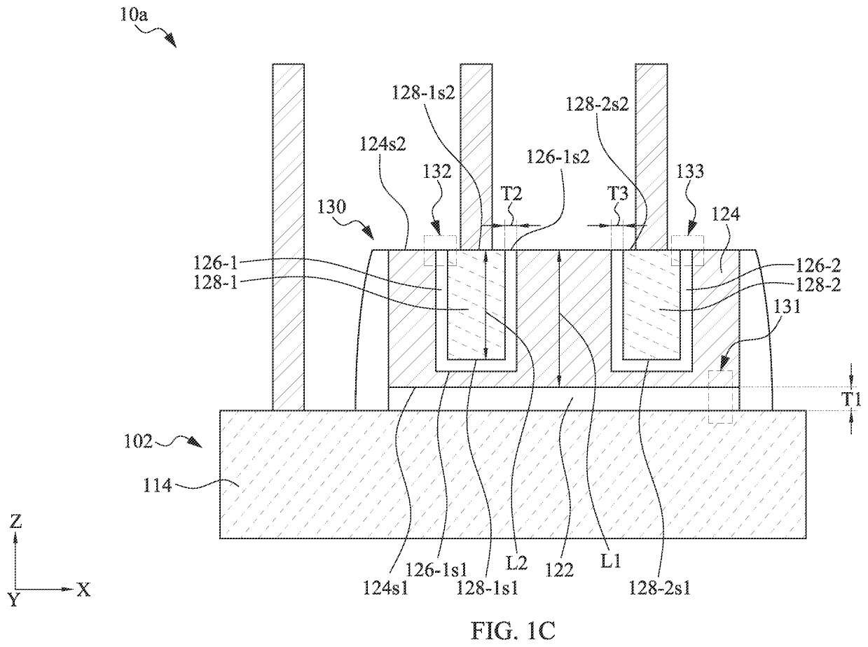

FIG. 1A and FIG. 1B illustrate a semiconductor device 10a in accordance with some embodiments of the present disclosure, wherein FIG. 1A is a top view, and FIG. 1B is a cross-sectional view along line A-A′ in FIG. 1A.

The semiconductor device 10a includes a substrate 102. In some embodiments, the substrate 102 is a semiconductor substrate, such as a bulk semiconductor substrate, a semiconductor-on-insulator (SOI) substrate, or the like, which may be doped (e.g., with a p-type or an n-type dopant) or undoped. The substrate 102 may be a semiconductor wafer, such as a silicon wafer. Generally, an SOI substrate includes a layer of a semiconductor material (e.g., silicon) formed on an insulator layer. The insulator layer may be, for example, a buried oxide (BOX) layer, a silicon oxide layer, or the like. The insulator layer is provided on a substrate, typically silicon or glass substrate. Other substrates, such as a multi-layered or gradient substrate, may also be used. In some embodiments, the semiconductor material of the substrate 102 may include or be made of silicon, germanium, a compound semiconductor including silicon carbide (SiC), gallium arsenic (GaAs), gallium phosphide (GaP), indium phosphide (InP), indium arsenide (InAs), and/or indium antimonide (InSb), an alloy semiconductor including SiGe, GaAsP, AlInAs, AlGaAs, GaInAs, GaInP, and/or GaInAsP, or combinations thereof.

Depending on design requirements, the substrate 102 may be a p-type substrate, an n-type substrate, or a combination thereof and may have doped regions therein. The substrate 102 may be configured for an n-type metal-oxide-semiconductor (NMOS) device, a PMOS device, an n-type FinFET device, a p-type FinFET device, other kinds of devices (such as, multiple-gate transistors, gate-all-around transistors or nanowire transistors), or combinations thereof.

The semiconductor device 10a includes an isolation structure 104. The isolation structure 104 includes a shallow trench isolation (STI) region, which may be formed to extend from the upper surface (not annotated) of the substrate 102. In some embodiments, the isolation structure 104 includes a liner oxide (not shown), which may be a thermal oxide formed through a thermal oxidation of a surface layer of the substrate 102. The isolation structure 104 may also include a dielectric material over the liner oxide, wherein the dielectric material may be formed using flowable chemical vapor deposition (FCVD), spin-on, or the like. In some embodiments, the depth (or the thickness along the Z direction) of the isolation structure 104 ranges between 1500 Å to 4000 Å.

In some embodiments, the substrate 102 includes well regions 111, 112, and 113 as well as a doped region 114 for different purposes, such as measurement, leakage prevention, and adjustment of breakdown voltage.

The well region 111 is disposed within the substrate 102 and separated from the upper surface of the substrate 102. The well region 111 has a first conductive type, such as an n-type. The well region 111 may be formed by implanting an n-type dopant, such as phosphorus (P), at a concentration of between 2E15 atoms/cm³ and 3E15 atoms/cm³. The well region 111 may also be referred to as a deep N well (DNW) region. In some embodiments, an average depth (Rp) of dopants of the well region 111 in the substrate 102 is in a range of 1.5 μm to 2.5 μm from the upper surface of the substrate 102. As used herein, the term “Rp” indicates a depth of the middle of a well region or a doped region from the upper surface of the substrate 102. In some embodiments, a variance of the average depths (ΔRp) of the well region 111 is in a range of 0.2 μm to 0.4 μm.

The well region 112 is disposed within the substrate 102 and over the well region 111. In some embodiments, the well region 112 extends between the upper surface of the substrate 102 and the well region 111. The well region 111 has the first conductive type, such as an n-type. The well region 112 may be formed by implanting an n-type dopant, such as phosphorus (P), at a concentration of between 1E14 atoms/cm³ and 1E16 atoms/cm³. In some embodiments, the well region 112 contacts or overlaps the well region 111 along the Z direction. In some embodiments, the Rp of dopants of the well region 112 in the substrate 102 is in a range of 0.2 μm to 0.5 μm from the upper surface of the substrate 102. In some embodiments, the ΔRp of the well region 112 is in a range of 0.04 μm to 0.1 μm.

The well region 113 is disposed within the substrate 102 and surrounded by the well region 112. In some embodiments, the well region 113 extends between the upper surface of the substrate 102 and the well region 111. In some embodiments, the well region 113 contacts or overlaps the well region 111 along the Z direction. The well region 113 has a second conductive type different from the first conductive type, such as a p-type. The well region 113 may be formed by implanting a P-type dopant, such as boron (B), at a concentration of between 1E14 atoms/cm³ and 5E15 atoms/cm³. In some embodiments, the Rp of dopants of the well region 113 in the substrate 102 is in a range of 0.03 μm to 0.5 μm from the upper surface of the substrate 102. In some embodiments, the ΔRp of the well region 113 is in a range of 0.04 μm to 0.1 μm.

The doped region 114 is disposed within the substrate 102 and over the well region 113. In some embodiments, the doped region 114 is surrounded by the isolation structure 104. The doped region 114 has the first conductive type, such as an n-type. The doped region 114 may be formed by implanting an n-type dopant, such as phosphorus (P), arsenic (As), antimony (Sb), bismuth (Bi), or a combination thereof, at a concentration of between 1E17 atoms/cm³ and 8E17 atoms/cm³. In some embodiments, the doped region 114 functions as at least a portion of an electrode (e.g., lower electrode) of a capacitor structure, which will be described in detail later. In some embodiments, the depth of the doped region 114 is equal to or less than that of the isolation structure 104 so as to prevent lateral leakage from the doped region 114. In some embodiments, the Rp of dopants of the doped region 114 in the substrate 102 is in a range of 0.01 μm to 0.1 μm from the upper surface of the substrate 102. In some embodiments, the ΔRp of the doped region 114 is in a range of 0.007 μm to 0.02 μm.

The semiconductor device 10a includes a capacitor dielectric 122. The capacitor dielectric 122 is disposed on the substrate 102. In some embodiments, the capacitor dielectric 122 overlaps the doped region 114 along the Z direction. In some embodiments, the capacitor dielectric 122 overlaps the well region 113 along the Z direction. The capacitor dielectric 122 includes one or more suitable dielectric materials such as silicon oxide (SiO₂), silicon nitride (Si₃N₄), silicon oxynitride (SiON), low-k dielectrics such as carbon doped oxides, extremely low-k dielectrics such as porous carbon doped silicon dioxide, a polymer such as polyimide, the like, or a combination thereof. In other embodiments, the capacitor dielectric 122 includes dielectric materials having a high dielectric constant (k value), for example, greater than 3.9. The materials may include metal oxides such as hafnium oxide (HfO₂), hafnium zirconium oxide (HfZrOₓ), hafnium silicon oxide (HfSiOₓ), hafnium titanium oxide (HfTiOₓ), hafnium aluminum oxide (HfAlOₓ), titanium nitride (TiN), yttrium oxide (Y₂O₃), zirconium oxide (ZrO₂), the like, or a combination thereof.

The semiconductor device 10a includes an electrode 124. The electrode 124 is disposed on the capacitor dielectric 122. In some embodiments, the electrode 124 overlaps the doped region 114 along the Z direction. In some embodiments, the electrode 124 overlaps the well region 113 along the Z direction. A portion of the doped region 114 is exposed by the electrode 124. The electrode 124 is separated from the doped region 114 by the capacitor dielectric 122. In some embodiments, the electrode 124 includes a semiconductor material, such as polysilicon. In some embodiments, the electrode 124 includes a conductive material, such as tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru), or a combination thereof.

In some embodiments, the semiconductor device 10a includes a capacitor dielectric 126-1 and a capacitor dielectric 126-2. In some embodiments, each of the capacitor dielectrics 126-1 and 126-2 is embedded within the electrode 124. In some embodiments, the capacitor dielectric 126-1 (or 126-2) is separated from the capacitor dielectric 122. In some embodiments, a portion of the capacitor dielectric 122 is located between the substrate 102 and the capacitor dielectric 126-1 (or 126-2). Each of the capacitor dielectrics 126-1 and 126-2 includes one or more suitable dielectric materials such as silicon oxide (SiO₂), silicon nitride (Si₃N₄), silicon oxynitride (SiON), or other low-k dielectrics. In other embodiments, each of the capacitor dielectrics 126-1 and 126-2 includes dielectric materials having a high dielectric constant, such as hafnium oxide (HfO₂), hafnium zirconium oxide (HfZrOₓ), hafnium silicon oxide (HfSiOₓ), hafnium titanium oxide (HfTiOₓ), hafnium aluminum oxide (HfAlOₓ), titanium nitride (TiN), yttrium oxide (Y₂O₃), zirconium oxide (ZrO₂), the like, or a combination thereof.

In some embodiments, the semiconductor device 10a includes an electrode 128-1 and an electrode 128-2. In some embodiments, each of the electrodes 128-1 and 128-2 is embedded within the electrode 124. The electrode 128-1 is separated from the electrode 124 by the capacitor dielectric 126-1. The electrode 128-2 is separated from the electrode 124 by the capacitor dielectric 126-2. In some embodiments, each of the electrodes 128-1 and 128-2 includes a conductive material, such as tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru) or a combination thereof.

In some embodiments, the doped region 114 is N-type and the electrode 124 is or comprises a metal or a metal compound with an N-type work function. Similarly, in some embodiments, the doped region 114 is N-type, and the electrode 128-1 and the electrode 128-2 are or comprises a metal or a metal compound with an N-type work function. An N-type work function may, for example, be about 3.9-4.5 electron volts (eV) or some other suitable value. In other embodiments, the doped region 114 is P-type and the electrode 124 is or comprises a metal or a metal compound with a P-type work function. Similarly, in some embodiments, the doped region 114 is P-type, and the electrode 128-1 and the electrode 128-2 are or comprises a metal or a metal compound with a P-type work function. A P-type work function may, for example, be about 4.6-5.2 eV or some other suitable value.

Referring to FIG. 1C, a partial enlarged view of FIG. 1B is provided. In some embodiments, the semiconductor device 10a includes a capacitor structure 130. In some embodiments, the electrode 124 functions as a first electrode (or upper electrode) of the capacitor structure 130. In some embodiments, each of the doped region 114 of the substrate 102, the electrode 128-1, and the electrode 128-2 functions as a second electrode (or lower electrode) of the capacitor structure 130. The pair of the first electrode and one of the second electrodes defines a capacitor. For example, the doped region 114 of the substrate 102, the capacitor dielectric 122, and the electrode 124 collectively define a capacitor 131. The electrode 124, the capacitor dielectric 126-1, and the electrode 128-1 collectively define a capacitor 132. The electrode 124, the capacitor dielectric 126-2, and the electrode 128-2 collectively define a capacitor 133.

In some embodiments, the capacitors 131, 132, and 133 are electrically connected in parallel. For example, a first power (or voltage) is imposed on the electrode 124, and a second power (or voltage) different from the first power is imposed on the doped region 114 of the substrate 102, the electrode 128-1, and the electrode 128-2. In some embodiments, the doped region 114 of the substrate 102, the electrode 128-1, and the electrode 128-2 are electrically connected to each other by a zero metal layer (e.g., M0), a first metallization layer (e.g., M1), a second metallization layer (e.g., M2), or other conductive traces formed over or within an interlayer dielectric (ILD).

The capacitance of a capacitor is negatively proportional to a distance between two electrodes. For example, the capacitance of the capacitor 131 is negatively proportional to the thickness T1 of the capacitor dielectric 122. The capacitance of the capacitor 132 is negatively proportional to the thickness T2 of the capacitor dielectric 126-1. The capacitance of the capacitor 133 is negatively proportional to the thickness T3 of the capacitor dielectric 126-2. In some embodiments, the thickness T1 of the capacitor dielectric 122 is different from the thickness T2 of the capacitor dielectric 126-1. In other embodiments, the thickness T1 of the capacitor dielectric 122 may be substantially the same as the thickness T2 of the capacitor dielectric 126-1. In some embodiments, the thickness T2 of the capacitor dielectric 126-1 is substantially the same as the thickness T3 of the capacitor dielectric 126-2. The total capacitance of the capacitor structure 130 is identical to the sum of the capacitances of the capacitors 131, 132, and 133. In this embodiment, some of second electrodes (e.g., the electrodes 128-1 and 128-2) are disposed within the electrode 124, which increases the total capacitance without additional spaces to form the second electrodes.

In some embodiments, the electrode 128-1 and the electrode 128-2 are collectively closer to a first side of the capacitor structure 130 than a second side of the capacitor structure opposite the first side. Further, in some embodiments, the capacitor structure 130 may have an asymmetric cross-sectional profile about a vertical axis (e.g., an axis extending in the Z direction) that is at a width-wise center of the electrode 124.

In some embodiments, a surface 124s1 (or a lower surface) of the electrode 124 has an elevation, with respect to the substrate 102, lower than that of a surface 128-1s1 (or a lower surface) of the electrode 128-1. In some embodiments, the surface 124s1 of the electrode 124 has an elevation, with respect to the substrate 102, lower than that of a surface 128-2s1 (or a lower surface) of the electrode 128-2. In some embodiments, a surface 124s2 (or an upper surface) of the electrode 124 has an elevation, with respect to the substrate 102, substantially the same as that of a surface 128-1s2 (or an upper surface) of the electrode 128-1. In some embodiments, the surface 124s2 of the electrode 124 has an elevation, with respect to the substrate 102, substantially the same as that of a surface 128-2s2 (or an upper surface) of the electrode 128-2. In some embodiments, a portion of the electrode 124 is disposed between the electrode 128-1 and the doped region 114 of the substrate 102.

In some embodiments, the surface 128-1s2 of the electrode 128-1 has an elevation, with respect to the substrate 102, substantially the same as that of the surface 128-2s2 of the electrode 128-2. In some embodiments, a surface 126-1s1 (or a lower surface) of the capacitor dielectric 126-1 has an elevation between those of the electrodes 124 and 128-1. In some embodiments, a surface 126-1s2 (or an upper surface) of the capacitor dielectric 126-1 has an elevation, with respect to the substrate 102, substantially the same as that of the surface 124-1s2 of the electrode 124. In some embodiments, the capacitor dielectric 122 has an elevation, with respect to the substrate 102, lower than that of the capacitor dielectric 126-1 (or 126-2). In some embodiments, the surfaces 124s2 of the electrode 124, the surface 126-1s2 of the capacitor dielectric 126-1, and the surface 128-1s2 of the electrode 128-1 are substantially coplanar.

In some embodiments, the electrode 124 has a length L1 (or thickness) along the Z direction, and the electrode 128-1 has a length L2 (or thickness), along the Z direction, less than the length L1 of the electrode 124.

Although FIGS. 1A, 1B, and 1C illustrate that the capacitor structure 130 includes two electrodes 128-1 and 128-2 embedded within the electrode 124, the capacitor structure 130 can include three or more electrodes embedded within the electrodes 124 in other embodiments, depending on electrical requirements of the semiconductor device 10a.

Referring back to FIG. 1B, the semiconductor device 10a includes a spacer structure 140. The spacer structure 140 is disposed on the substrate 102. The spacer structure 140 is disposed on two opposite surfaces (e.g., lateral surfaces) of the electrode 124. In some embodiments, the spacer structure 140 sandwiches the electrodes 124, 128-1, and 128-2. In some embodiments, the spacer structure 140 includes a dielectric material such as silicon nitride, silicon oxide, silicon carbo-nitride, silicon oxynitride, silicon oxy-carbo-nitride, or the like, and may have a single-layer structure or a multi-layer structure including a plurality of dielectric layers.

The semiconductor device 10a includes doped regions 152, 154, and 156. The doped regions 152 and 156 are disposed on two opposite sides of the capacitor structure 130. The doped regions 152 and 156 are disposed on two opposite sides of the electrode 124. Each of the doped regions 152 and 156 is disposed within the well region 112 of the substrate 102. Each of the doped regions 152 and 156 has the first conductive type, such as an n-type. The doped regions 152 and 156 may be formed by implanting an n-type dopant, such as phosphorus (P). The doping concentration of the doped region 152 (or 156) is greater than that of the well region 112. The doped regions 152 and 156 may function as a pickup ring for the purpose of adjustment of breakdown voltage.

The doped region 154 is disposed within the well region 113 of the substrate 102. The doped region 154 has the second conductive type, such as a p-type. The doped region 154 may be formed by implanting a p-type dopant, such as boron (B). The doping concentration of the doped region 154 is greater than that of the well region 113. In some embodiments, the doped region 154 is for the purpose of measurement and examination of the capacitor structure 130. For example, the doped region 154 may be configured to measure current or leakage to the well region 113. The function and performance of the semiconductor device 10a are not affected by an absence of the doped region 154. As such, the doped region 154 is optionally formed in the substrate 102.

The semiconductor device 10a includes a dielectric structure 160. In some embodiments, the dielectric structure 160 includes a multi-layered structure. For example, the dielectric structure 160 may include a contact etch stop layer (CESL), an inter-layer dielectric (ILD), and other suitable layers. The CESL may include or be made of silicon nitride, silicon carbo-nitride, or the like, and may be formed using a conformal deposition technique, such as atomic layer deposition (ALD) or chemical vapor deposition (CVD). The ILD may include a dielectric material formed using, for example, FCVD, spin-on coating, CVD, or another deposition technique. The ILD may also be formed of an oxygen-containing dielectric material, which may include silicon-oxide based materials such as tetra ethyl ortho silicate (TEOS) oxide, plasma-enhanced CVD (PECVD) oxide (SiO₂), phospho-silicate glass (PSG), boron-silicate glass (BSG), boron-doped phospho-silicate glass (BPSG), or other suitable materials.

The semiconductor device 10a includes conductive contacts 170-1, 170-2, 170-3, 170-4, 170-5, 170-6, and 170-7. Each of the conductive contacts 170-1 to 170-7 is disposed on the substrate 102 and embedded within the dielectric structure 160. The conductive contact 170-1 is disposed on and electrically connected to the doped region 114. The conductive contact 170-2 is disposed on and electrically connected to the electrode 124. The conductive contact 170-3 is disposed on and electrically connected to the electrode 128-1. The conductive contact 170-4 is disposed on and electrically connected to the electrode 128-2. The conductive contact 170-5 is disposed on and electrically connected to the doped region 152. The conductive contact 170-6 is disposed on and electrically connected to the doped region 154. The conductive contact 170-7 is disposed on and electrically connected to the doped region 156. Each of the conductive contacts 170-1 to 170-7 includes conductive materials, such as metal, metal nitride, alloy or other suitable materials. Each of the conductive contacts 170-1 to 170-7 is electrically connected to a power supply through metal traces (e.g., M0, M1, M2, or the like), and thus provides the corresponding features with a needed power (or voltage). The location and/or the number of the conductive contacts 170-1 to 170-7 is merely an exemplary embodiment, and the present disclosure is not intended to be limiting. Although not shown in FIG. 1A to FIG. 1C, it should be noted that the conductive contacts 170-1, 170-3, and 170-4 are electrically connected by metal traces (e.g., M0, M1, M2, or the like) formed over the dielectric structure 160.

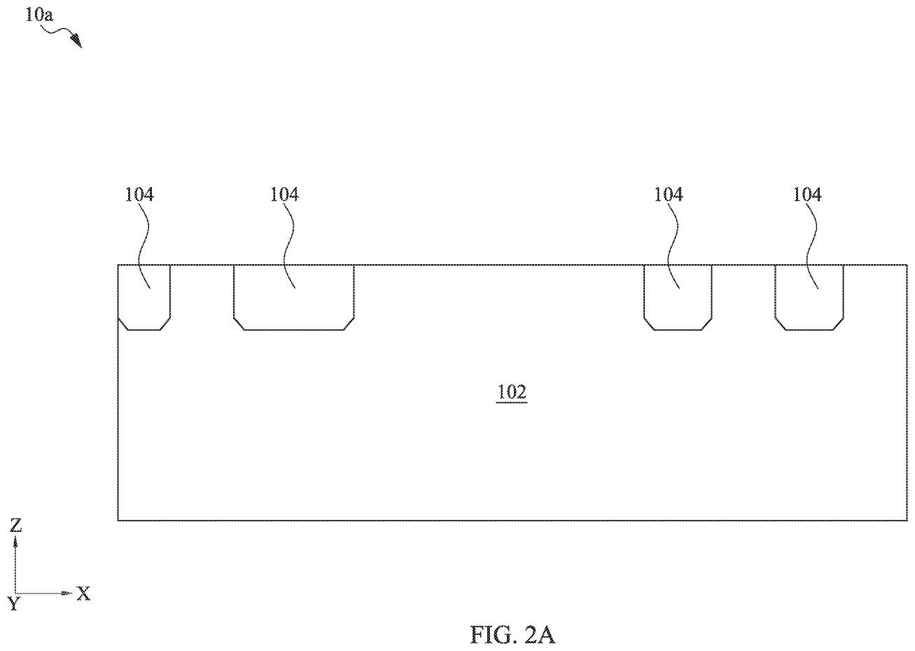

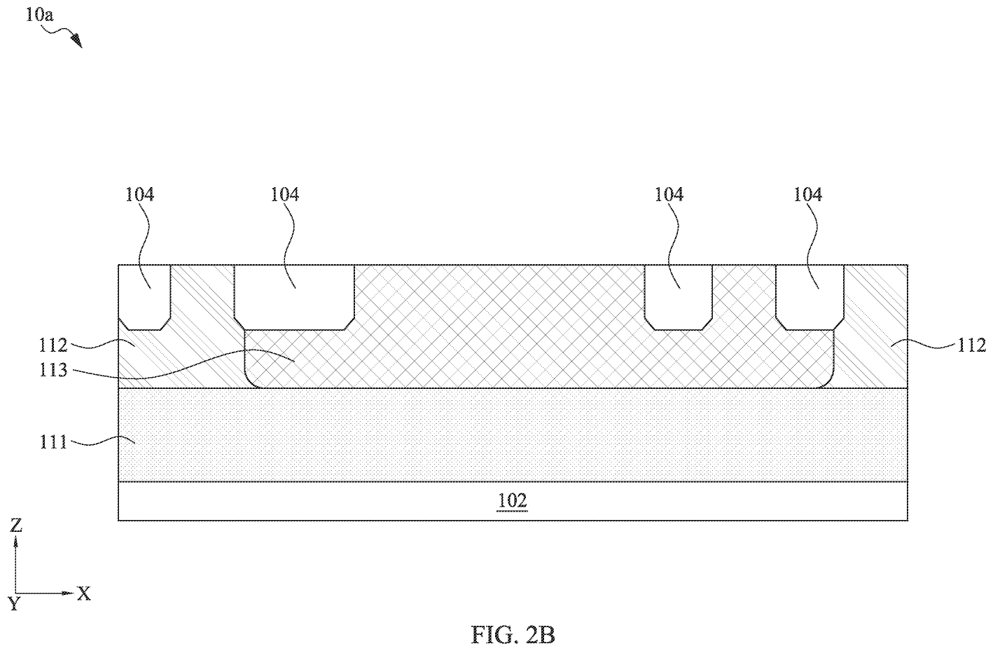

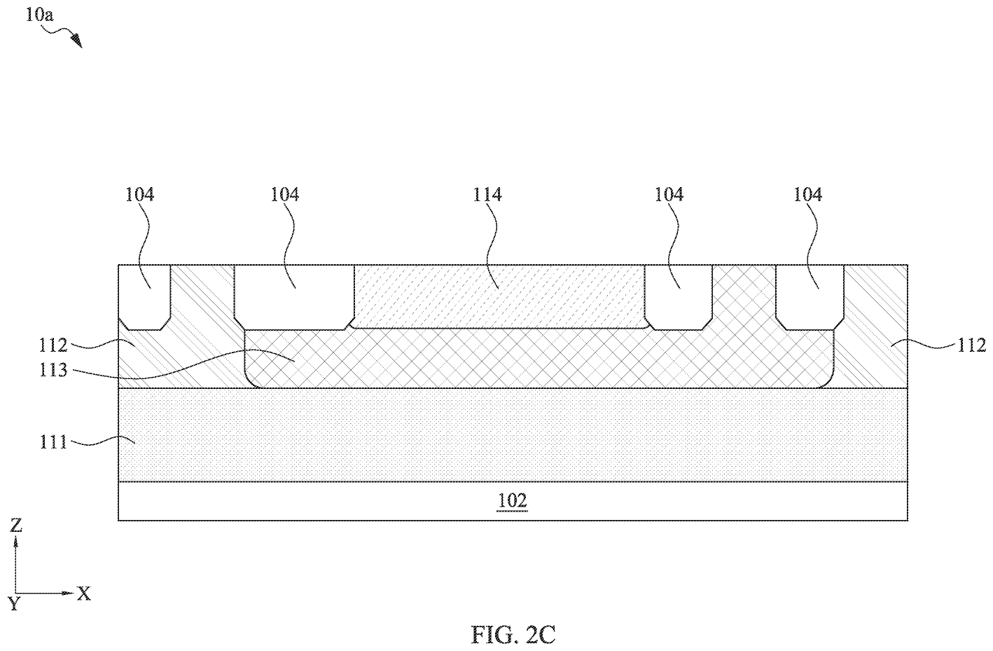

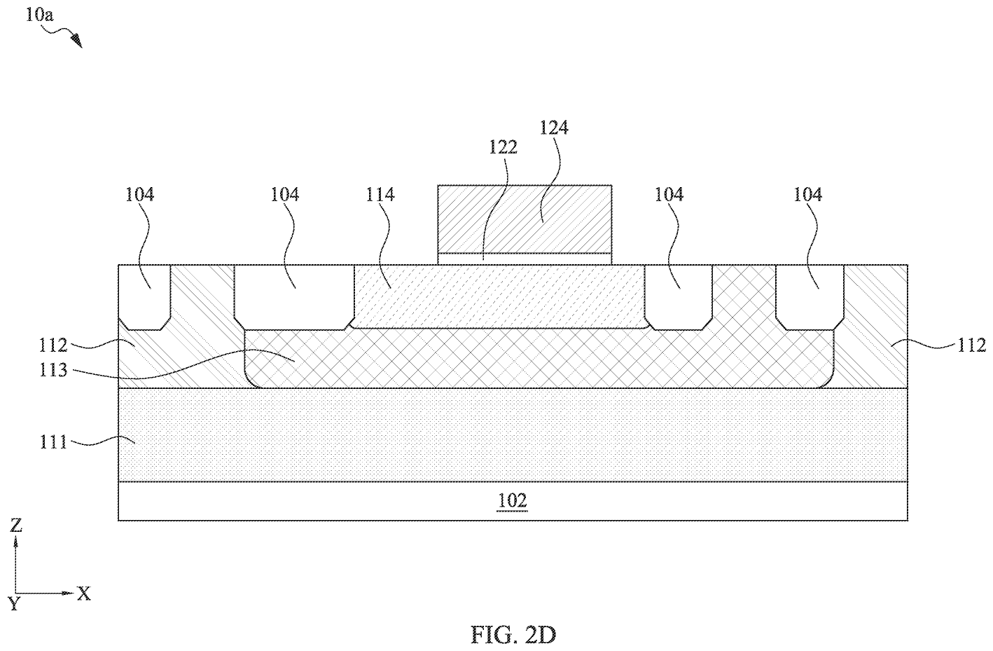

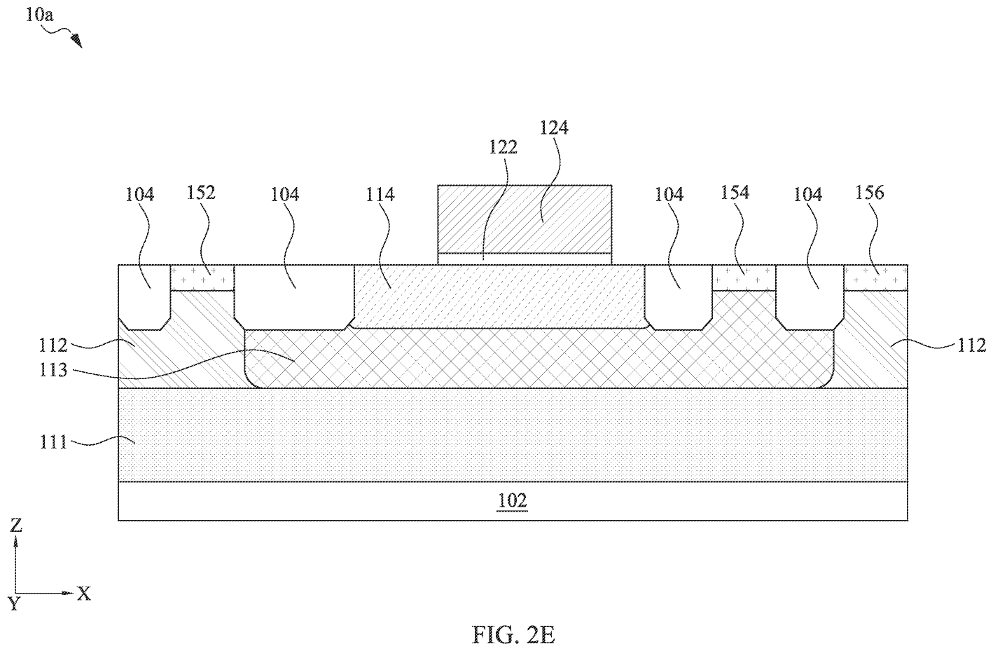

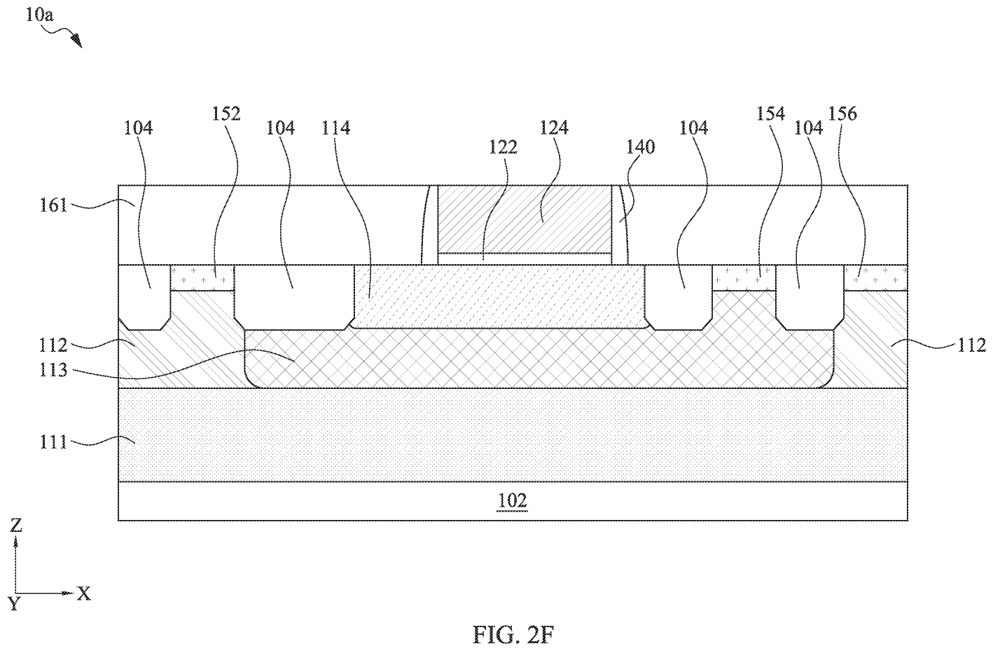

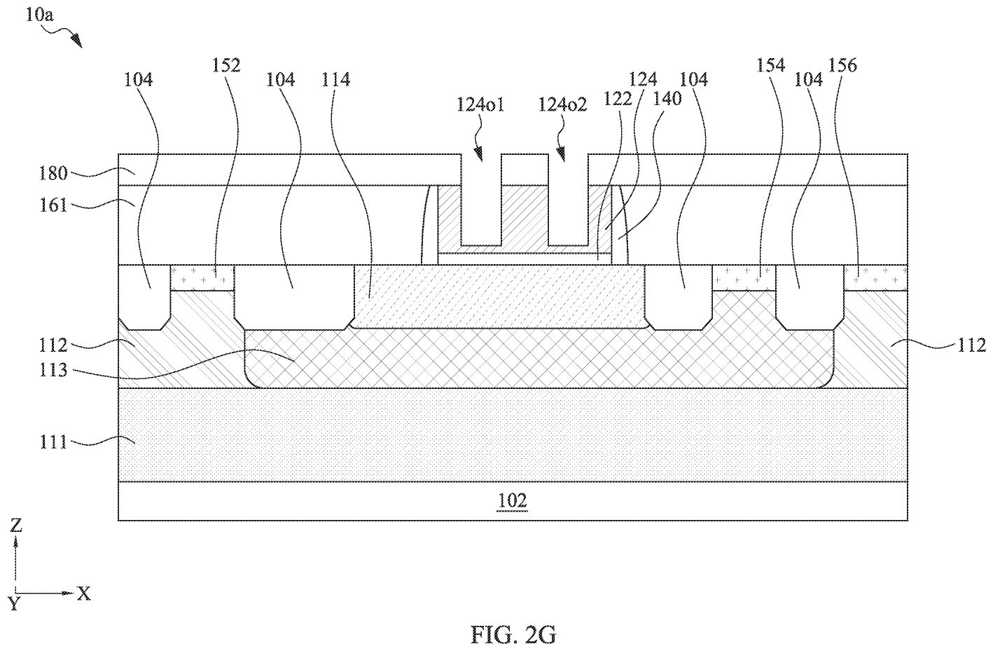

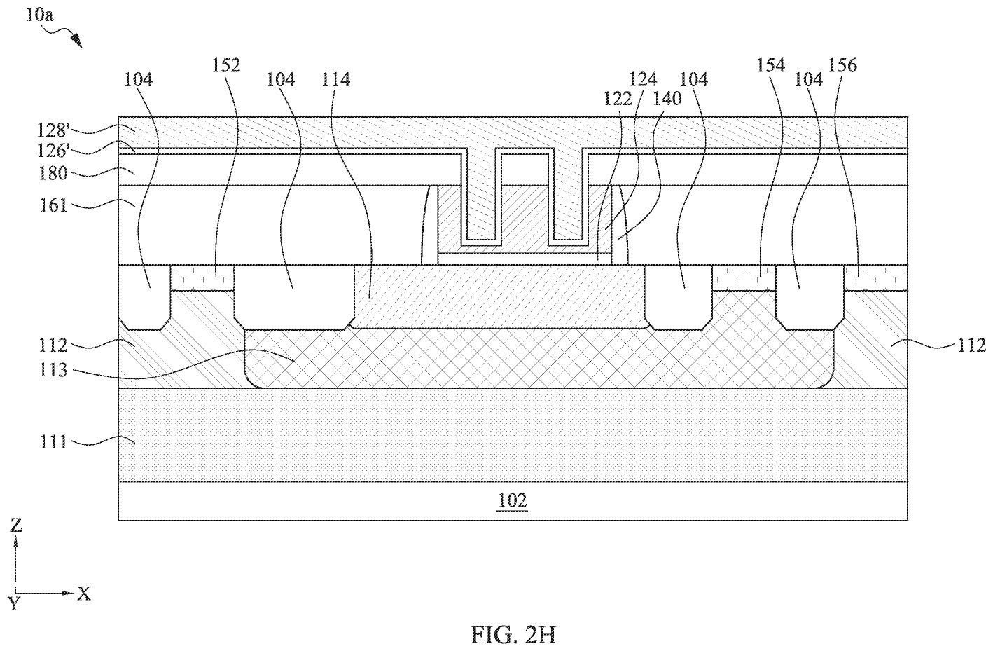

FIG. 2A to FIG. 2J illustrate various stages of manufacturing a semiconductor device (e.g., the semiconductor device 10a as shown in FIG. 1A to FIG. 1C), in accordance with some embodiments of the present disclosure.

Referring to FIG. 2A, the substrate 102 is provided. The isolation structure 104 is formed within the substrate 102. An etching technique may be performed on the substrate 102 to remove portions of the substrate 102, and a deposition technique can be performed to form the isolation structure 104. In some embodiments, the deposition operation includes a chemical vapor deposition (CVD), a physical vapor deposition (PVD), a liquid-phase deposition (LPD), an atmospheric-pressure CVD (APCVD), an atomic layer deposition (ALD), a sub-atmospheric CVD (SACVD), a low-pressure chemical vapor deposition (LPCVD), a plasma-enhanced CVD (PECVD), or a combination thereof. In some embodiments, the isolation structure 104 is substantially coplanar with the upper surface of the substrate 102. In some embodiments, the isolation structure 104 protrudes from the upper surface of the substrate 102. A width of different portions of the isolation structure 104 or a distance between adjacent portions of the isolation structure 104 can be adjusted according to different applications.

Referring to FIG. 2B, the well region 111 is formed within the substrate 102. The well region 111 can be formed by an implantation to introduce dopants of the first conductive type (e.g., n-type) into the substrate 102. It should be noted that a conductivity type described herein is for the purpose of illustration, but not intended to limit the present disclosure. In some embodiments, a photoresist layer is formed to define the well region 111 (not shown). In some embodiments, pre-cleaning, photoresist application (formation of the photoresist layer), exposure, developing and the implantation are sequentially performed to form the well region 111. The well regions 112 and 113 are defined in the substrate 102 above the well region 111. A sequence of implantations may be performed to form the well regions 112 and 113. In some embodiments, the well regions 112 and 113 are formed after the forming of the well region 111. In some embodiments, the well region 112 is formed prior to the forming of the well region 113. In some embodiments, an implantation of dopants of the first conductive type (e.g., n-type) is performed to form the well region 112, and then an implantation of dopants of the second conductive type (e.g., p-type) is performed to form the well region 113 in the well region 112. In other embodiments, the well region 112 is formed after the forming of the well region 113, and similar processes can be provided but with a reversed sequence of implantations.

Referring to FIG. 2C, the doped region 114 is formed within the well region 113. In some embodiments, an implantation of dopants of the first conductive type (e.g., n-type) is performed to form the doped region 114.

Referring to FIG. 2D, the capacitor dielectric 122 and electrode 124 are formed over the doped region 114 of the substrate 102. In some embodiments, the capacitor dielectric 122 is formed by thermal oxidation, CVD, ALD, or other suitable techniques. In some embodiments, the electrode 124 is formed by CVD, ALD, or other suitable techniques. In some embodiments, a dielectric material layer is formed on the upper surface of the substrate 102 by a thermal oxidation technique, and a semiconductor material layer (e.g., polysilicon) is formed over the dielectric material layer. Next, an etching technique(s) is performed to pattern the dielectric material layer and semiconductor material layer, which thereby defines the capacitor dielectric 122 and the electrode 124.

Referring to FIG. 2E, the doped regions 152, 154, and 156 are formed. In some embodiments, an implantation of dopants of the first conductive type (e.g., n-type) is performed to form the doped regions 152 and 156; and an implantation of dopants of the second conductive type (e.g., p-type) is performed to form the doped region 154.

Referring to FIG. 2F, the spacer structure 140 is formed on the substrate 102 and on two opposite sides of the electrode 124. A dielectric layer 161 is formed to cover the substrate 102. In some embodiments, one or more dielectric layers are conformally formed on the electrode 124 and the substrate 102 by ALD, CVD, FCVD, or other suitable techniques to define the spacer structure 140. An etching technique (e.g., dry etching technique) is performed to remove a portion of the spacer structure 140, thereby exposing the doped regions 152, 154, and 156. Next, the dielectric layer 161 is formed to cover the spacer structure 140. The dielectric layer 161 may include one or more dielectric materials formed by CVD, ALD, or other suitable techniques. A chemical mechanical polishing (CMP) technique is performed to remove a portion of the dielectric layer 161 and the spacer structure 140. As a result, the electrode 124 is exposed. It should be noted that the sequence of forming the doped regions 152, 154, and 156 as well as the spacer structure 140 can be adjusted. For example, the doped regions 152, 154, and 156 may be formed after forming the spacer structure 140.

Referring to FIG. 2G, a mask 180 is formed to cover the dielectric layer 161, the spacer structure 140, and the electrode 124. The mask 180 includes, for example, a photosensitive material. The mask 180 is formed by, for example, coating or other suitable techniques. The mask 180 defines openings that expose a portion of the electrode 124. Next, an etching technique (e.g., a dry etching or wet etching) is performed to remove said portion of the electrode 124, which thereby forms openings 124o1 and 124o2. The depth of the openings 124o1 and 124o2 can be adjusted by the process time and/or other parameters of etching equipment.

Referring to FIG. 2H, a dielectric material layer 126′ and a conductive material layer 128′ are formed over the mask 180 and within the openings 124o1 and 124o2. The dielectric material layer 126′ is configured to form the capacitor dielectrics 126-1 and 126-2 in subsequent stages. The conductive material layer 128′ is configured to form the electrodes 128-1 and 128-2 in subsequent stages. The dielectric material layer 126′ is formed by ALD, CVD, or other suitable techniques. The conductive material layer 128′ is formed by PVD, CVD, ALD, or other suitable techniques.

Referring to FIG. 2I, the mask 180 is removed. A portion of the dielectric material layer 126′ and conductive material layer 128′ are removed to define the capacitor dielectrics 126-1 and 126-2 as well as the electrodes 128-1 and 128-2. In some embodiments, a CMP technique is performed to planarize the dielectric material layer 126′ and conductive material layer 128′ until the electrode 124 is exposed. As a result, the upper surfaces of the electrode 124, capacitor dielectric 126-1, capacitor dielectric 126-2, electrode 128-1, and electrode 128-2 are substantially aligned or coplanar.

Referring to FIG. 2J, a dielectric layer 162 is formed to cover the dielectric layer 161, which thereby defines the dielectric structure 160. The dielectric layer 162 may include one or more dielectric materials formed by CVD, ALD, or other suitable techniques. Next, the conductive contacts 170-1 to 170-7 are formed. As a result, the semiconductor device 10a is produced. In some embodiments, after the formation of dielectric structure 160, one or more etching techniques are performed to form openings, which exposes the substrate 102, and the electrodes 124, 128-1 and 128-2. Next, one or more conductive materials are formed to fill said openings to define the conductive contacts 170-1 to 170-7.

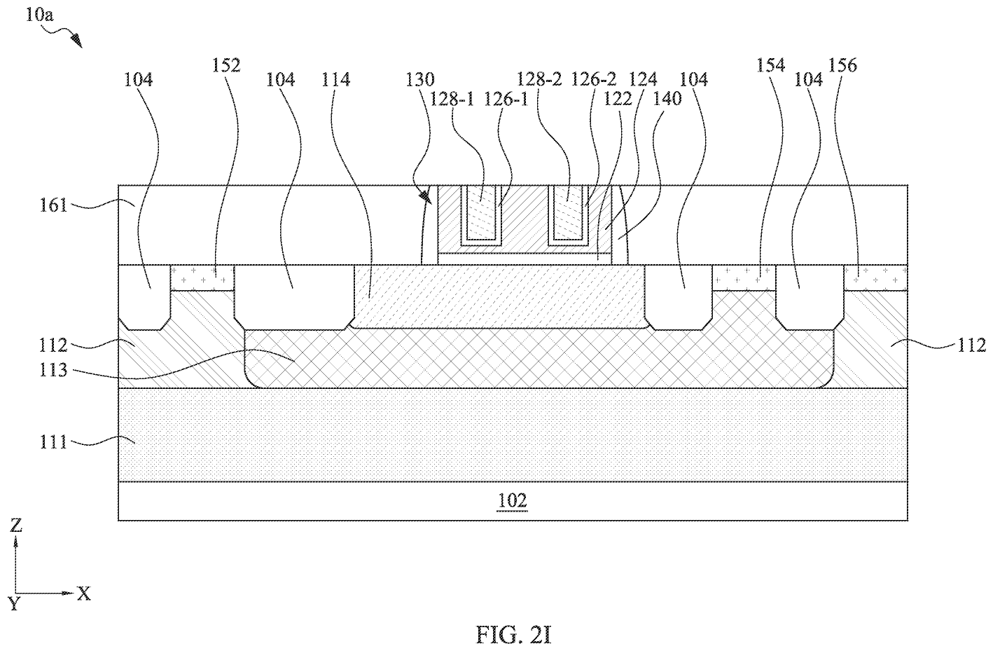

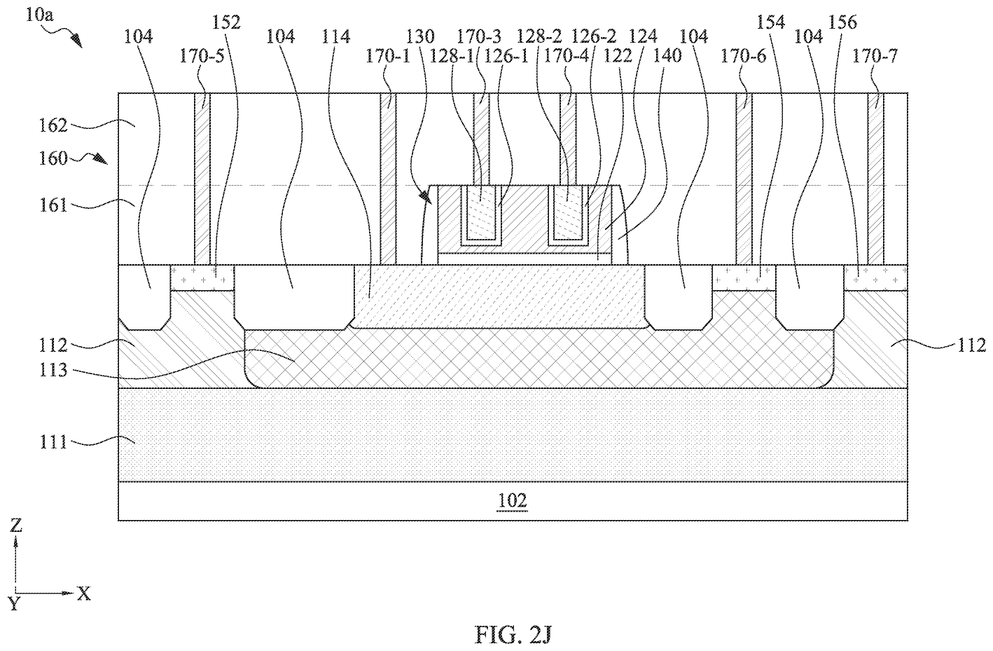

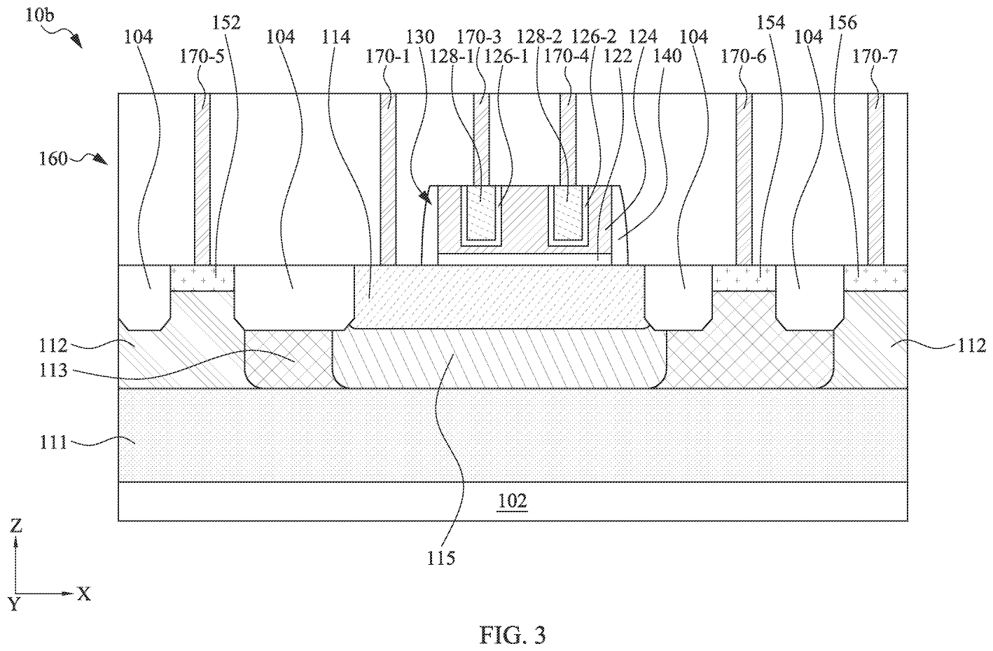

FIG. 3 illustrates a cross-sectional view of a semiconductor device 10b, in accordance with some embodiments of the present disclosure. The semiconductor device 10b may be similar to the semiconductor device 10a, with differences therebetween as follows.

In some embodiments, the semiconductor device 10b includes a well region 115. The well region 115 is disposed within the substrate 102 and extends between the well region 111 and the doped region 114. In some embodiments, the electrode 124 overlaps the well region 115 along the Z direction. The well region 115 has the second conductive type, such as a p-type. The well region 115 may be formed by implanting a p-type dopant, such as boron (B), at a concentration of between 3E14 atoms/cm³ and 1E16 atoms/cm³. In some embodiments, the doping concentration of the well region 115 is greater than that of the well region 113. In some embodiments, the Rp of dopants of the well region 115 in the substrate 102 is in a range of 0.2 μm to 0.5 μm from the upper surface of the substrate 102. In some embodiments, the ΔRp of the well region 115 is in a range of 0.04 μm to 0.1 μm.

For the purpose of leakage prevention, a width, along the X direction, of the well region 115 is substantially equal to or greater than the width of the doped region 114. In some embodiments, the well region 115 contacts the entirety of the bottom of the doped region 114. In some embodiments, the well region 115 covers the lower corner of the doped region 114 for the purpose of better prevention of lateral leakage.

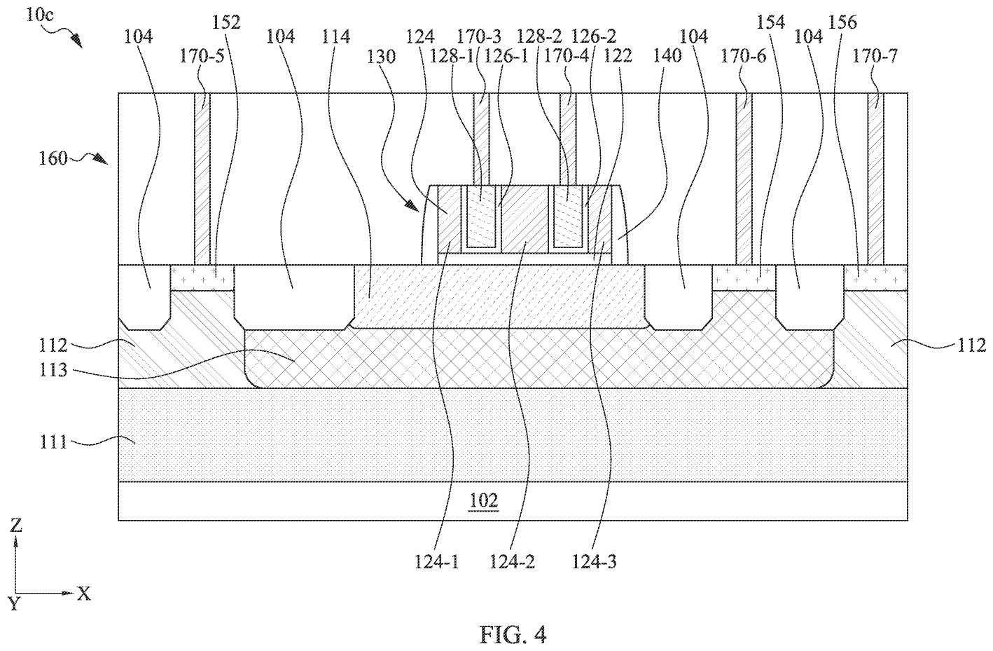

FIG. 4 illustrates a cross-sectional view of a semiconductor device 10c, in accordance with some embodiments of the present disclosure. The semiconductor device 10c may be similar to the semiconductor device 10a, with differences therebetween as follows.

In some embodiments, the capacitor dielectric 126-1 is in contact with the capacitor dielectric 122. The capacitor dielectric 126-2 is in contact with the capacitor dielectric 122. In some embodiments, the electrode 124 defines parts 124-1, 124-2, and 124-3, all of which are physically separated from each other by the capacitor dielectrics 126-1 and 126-2. In this embodiment, more contact features are used to electrically connect the parts 124-1, 124-2, and 124-3 of the electrode 124. In this embodiment, since the overlapping area between the electrodes 128-1 and 124 (or between the electrodes 128-2 and 124) along the X direction increases, the total capacitance of the capacitor structure 130 is enhanced.

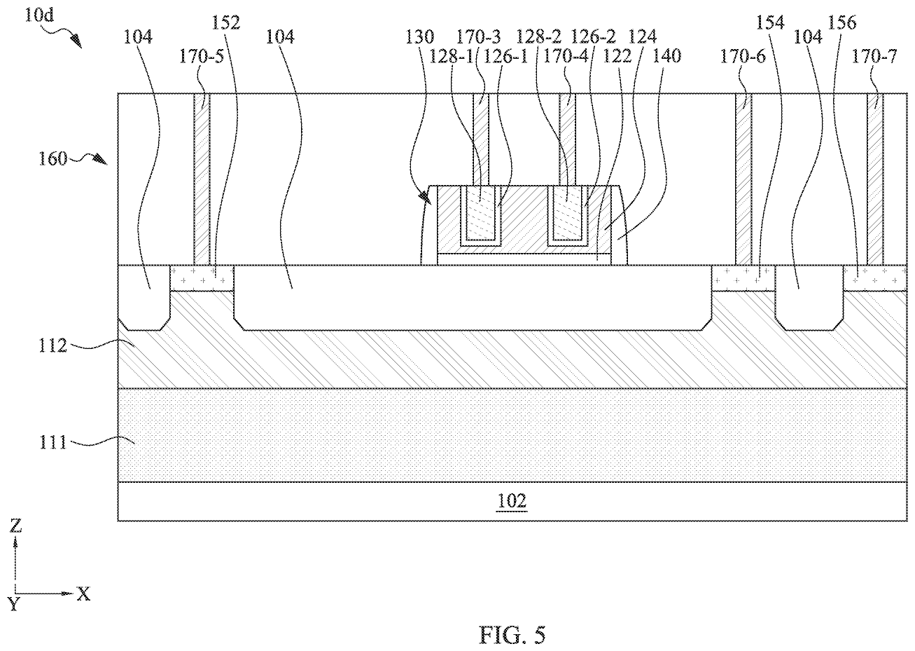

FIG. 5 illustrates a cross-sectional view of a semiconductor device 10d, in accordance with some embodiments of the present disclosure. The semiconductor device 10d may be similar to the semiconductor device 10a, with differences therebetween as follows.

In some embodiments, the electrode 124 is disposed on the isolation structure 104. The electrode 124 overlaps the isolation structure 104 along the Z direction. In some embodiments, the capacitor structure 130 is disposed on the isolation structure 104. The capacitor structure 130 overlaps the isolation structure 104 along the Z direction. In some embodiments, the capacitor dielectric 122 is in contact with the isolation structure 104. In this embodiment, the second electrodes of the capacitor structure 130 are defined by or constituted of the electrodes 128-1 and 128-2. The well region 113 and the doped region 114 as shown in FIG. 1B can be omitted. In this embodiment, the leakage between the substrate 102 and the capacitor structure 130 can be avoided by the isolation structure 104.

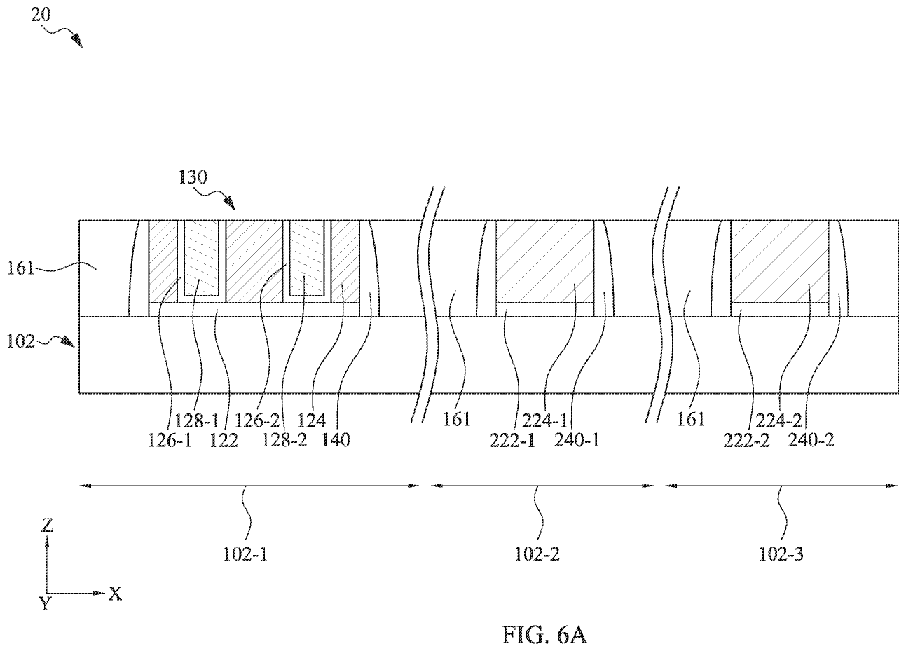

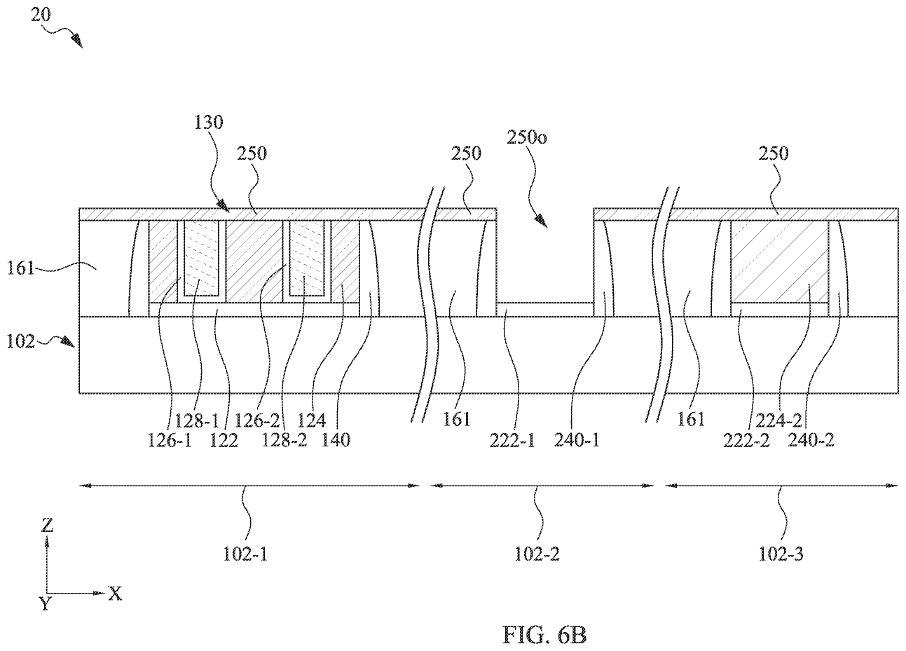

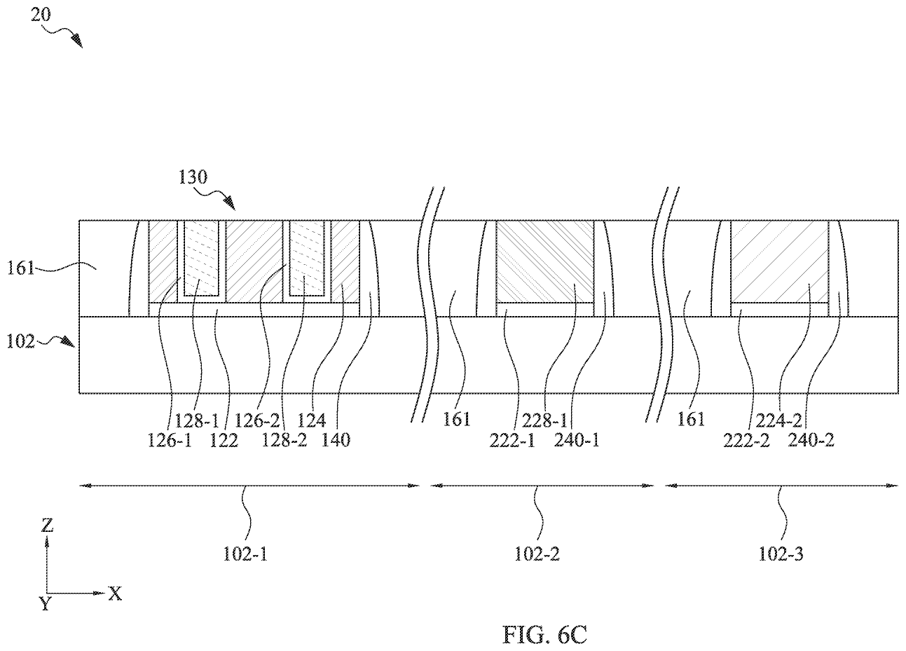

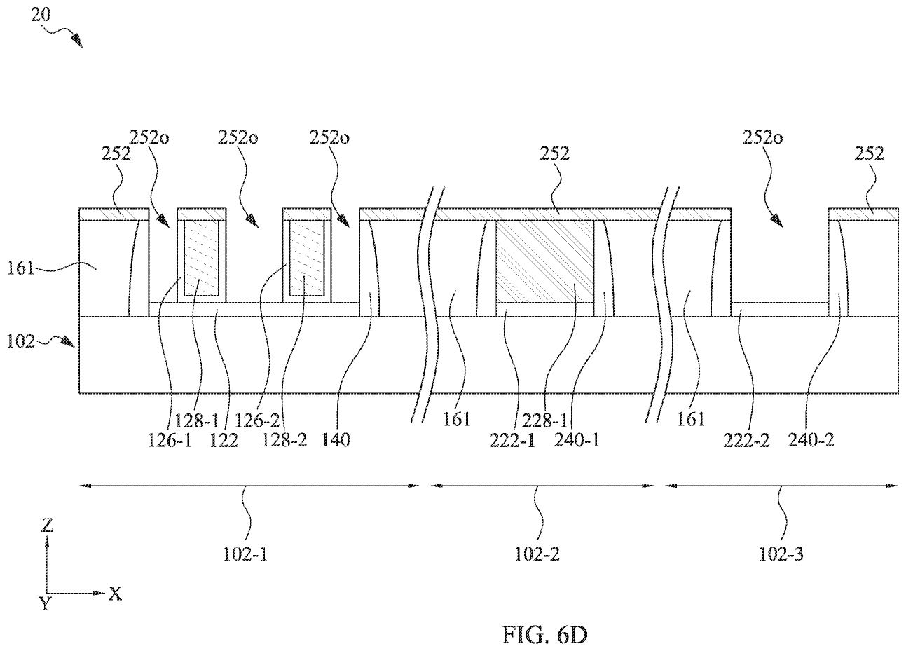

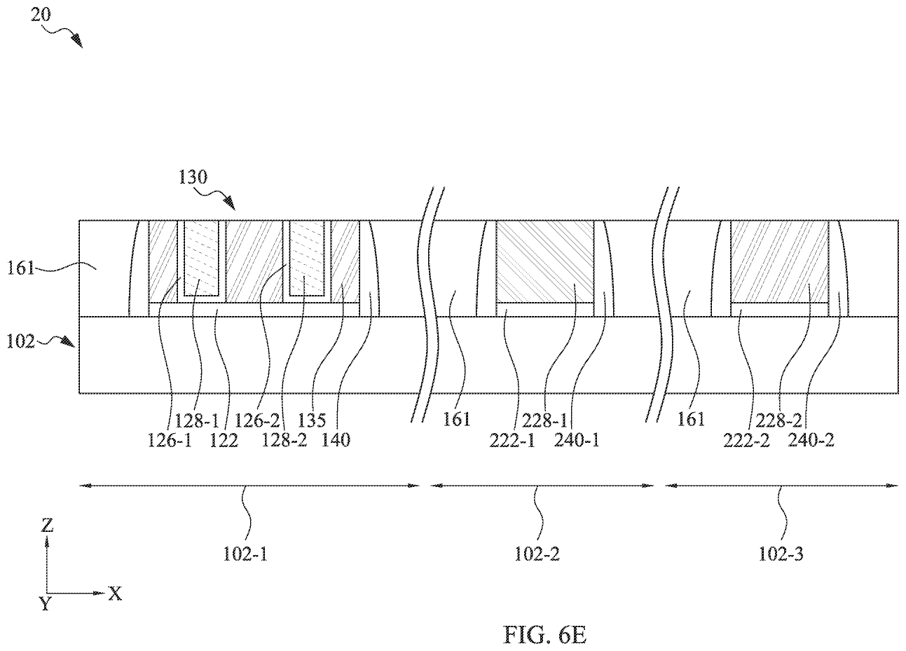

FIG. 6A to FIG. 6E illustrate various stages of manufacturing a semiconductor device 20, in accordance with some embodiments of the present disclosure. In some embodiments, at least a portion of the processes of manufacturing the semiconductor devices 10a to 10d can be integrated with those of manufacturing a logic device(s). FIG. 6A to FIG. 6E illustrate an exemplary embodiment wherein dummy gates are replaced with metal gate electrodes, and a dummy capacitor electrode is replaced with a metal capacitor electrode.

Referring to FIG. 6A, the substrate 102 includes regions 102-1, 102-2, and 102-3. The region 102-1 is configured to define a device (e.g., an NMOS capacitor) including the capacitor structure 130. The region 102-2 is configured to define a PMOS device. The region 102-3 is configured to define an NMOS device.

A gate dielectric 222-1 and a dummy gate 224-1 are formed on the region 102-2 of the substrate 102. A spacer structure 240-1 is formed on two opposite sides of the dummy gate 224-1. A gate dielectric 222-2 and a dummy gate 224-2 are formed on the region 102-3 of the substrate 102. A spacer structure 240-2 is formed on two opposite sides of the dummy gate 224-2. The material of the gate dielectrics 222-1 and 222-2 may be the same as or similar to that of the capacitor dielectric 122. The material of the dummy gates 224-1 and 224-2 may be the same as or similar to that of the electrode 124. The material of the spacer structures 240-1 and 240-2 may be the same as or similar to that of the spacer structure 140. The manufacturing processes prior to the stage as shown in FIG. 6A may include the stages as shown in FIG. 2A to FIG. 2I. Further, the manufacturing processes of forming the gate dielectric 222-1, gate dielectric 222-2, dummy gate 224-1, dummy gate 224-2, spacer structure 240-1, and spacer structure 240-2 can be integrated with those as shown in FIG. 2D to FIG. 2F. During the stages of manufacturing the electrodes 128-1 and 128-2 (e.g., the stages as shown in FIG. 2G and FIG. 2H), a mask (not shown) is formed on the region 102-2 and region 102-3 to protect the features from being influenced by etching techniques. The mask is removed after forming the electrodes 128-1 and 128-2, thereby exposing the dummy gates 224-1 and 224-2. Further, it should be noted that some features, such as doped regions, well regions, or other features are omitted for brevity. In this embodiment, the electrode 124, the dummy gates 224-1 and 224-2 are located at substantially the same elevation with respect to the substrate 102.

Referring to FIG. 6B, a mask 250 is formed to cover the dielectric layer 161. The mask 250 covers the electrode 124 and the dummy gate 224-2. The mask is patterned to define an opening 250o. The dummy gate 224-1 is removed. The gate dielectric 222-1 is exposed. In some embodiments, the mask 250 includes one or more dielectric layers, such as silicon oxide, silicon nitride, silicon oxynitride, or other suitable materials.

Referring to FIG. 6C, the mask 250 is removed, and a gate electrode 228-1 is formed within the opening 250o. In some embodiments, a conductive material is deposited to fill the opening 250o and covers the dielectric layer 161. Next, a CMP technique is performed to remove the upper portion of the conductive material. As a result, the upper surface of the gate electrode 228-1 is substantially aligned with the upper surface of the electrode 124 along the X direction. In some embodiments, the region 102-2 is configured to define a PMOS device, and the gate electrode 228-1 includes TiN, TaN, Ru, Mo, Al, WN, ZrSi₂, MoSi₂, TaSi₂, NiSi₂, WN, other suitable p-type work function materials, or combinations thereof.

Referring to FIG. 6D, a mask 252 is formed. Further, the mask 252 is patterned to define openings 252o in the region 102-1 and region 102-3. The electrode 124 is removed. The dummy gate 224-2 is removed. The capacitor dielectric 122 and the gate dielectric 222-2 are exposed.

Referring to FIG. 6E, an electrode 135 is formed within the opening 252o and on the region 102-1. A gate electrode 228-2 is formed within the opening 252o and on the region 102-3. In some embodiments, a conductive material is deposited to fill the openings 252o and cover the dielectric layer 161. Next, a CMP technique is performed to remove the upper portion of the conductive material. As a result, the upper surface of the electrode 135, the gate electrode 228-1, and the gate electrode 228-2 are substantially aligned with each other along the X direction. In some embodiments, the region 102-3 is configured to define an NMOS device, and the gate electrode 228-2 includes TaAlC, TaAl, TiAlC, TiAl, TaSiAl, TiSiAl, TaAlN, TiAlN, other suitable n-type work function materials, or combinations thereof. In this embodiment, the region 102-1 is configured to define an NMOS capacitor, and the processes of manufacturing the electrode 135 can be integrated with those of manufacturing the gate electrode 228-2. In this embodiment, the electrode 135 of the capacitor structure 130, the gate electrodes 228-1 and 228-2 are located at substantially the same elevation with respect to the substrate 102. In this embodiment, the lower surfaces of the electrode 135 of the capacitor structure 130, the gate electrodes 228-1 and 228-2 are located at substantially the same elevation with respect to the substrate 102. In this embodiment, the upper surfaces of the electrode 135 and the gate electrodes 228-1 and 228-2 are substantially aligned or coplanar. It should be noted that the removal of the electrode 124 is optional. When the electrode 124 functions as a dummy capacitor electrode, the electrode 124 is replaced by the electrode 135 depending on electrical requirements of the semiconductor device 20.

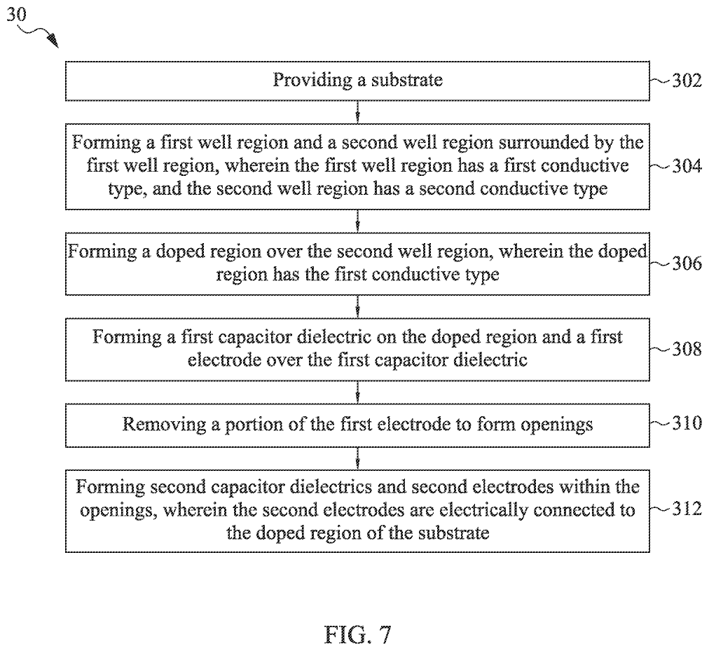

FIG. 7 is a flowchart of a method 30 for manufacturing a semiconductor device according to various aspects of the present disclosure.

The method 30 begins with operation 302 in which a substrate is provided. An isolation structure is formed within the substrate. FIG. 2A illustrates the stage corresponding to operation 302.

The method 30 continues with operation 304 in which a first well region, and a second well region are formed within the substrate. The second well region is surrounded by the first well region. The first well region has a first conductive type, and the second well region has a second conductive type. FIG. 2B illustrates the stage corresponding to operation 304.

The method 30 continues with operation 306 in which a doped region is formed over the second well region. The doped region has the first conductive type. FIG. 2C illustrates the stage corresponding to operation 306.

The method 30 continues with operation 308 in which a first capacitor dielectric is formed on the doped region of the substrate and a first electrode is formed over the first capacitor dielectric. FIG. 2D illustrates the stage corresponding to operation 308.

The method 30 continues with operation 310 in which a portion of the first electrode is removed to form openings. FIG. 2G illustrates the stage corresponding to operation 310.

The method 30 continues with operation 312 in which second capacitor dielectrics and second electrodes are formed within the openings. The doped region is electrically connected to the second electrodes. FIG. 2H to FIG. 2I illustrate the stage corresponding to operation 312.

The method 30 is merely an example and is not intended to limit the present disclosure beyond what is explicitly recited in the claims. Additional operations can be provided before, during, and after the method 30, and some operations described can be replaced, eliminated, or reordered for additional embodiments of the method.

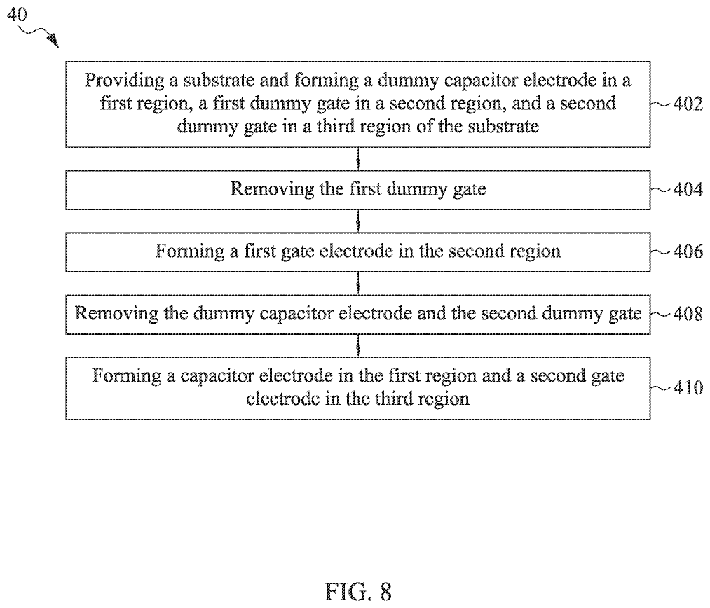

FIG. 8 is a flowchart of a method 40 for manufacturing a semiconductor device according to various aspects of the present disclosure.

The method 40 begins with operation 402 in which a substrate is provided. The substrate has a first region, a second region, and a third region. A dummy capacitor electrode is formed in the first region of the substrate. A first dummy gate is formed in the second region of the substrate. A second dummy gate is formed in the third region of the substrate. FIG. 6A illustrates the stage corresponding to operation 402.

The method 40 continues with operation 404 in which the first dummy gate is removed. FIG. 6B illustrates the stage corresponding to operation 404.

The method 40 continues with operation 406 in which a first gate electrode is formed in the second region of the substrate. FIG. 6C illustrates the stage corresponding to operation 406.

The method 40 continues with operation 408 in which the dummy capacitor electrode and the second dummy gate are removed. FIG. 6D illustrates the stage corresponding to operation 408.

The method 40 continues with operation 410 in which a capacitor electrode is formed in the first region of the substrate and a second gate electrode is formed in the third region of the substrate. FIG. 6E illustrates the stage corresponding to operation 410.

The method 40 is merely an example and is not intended to limit the present disclosure beyond what is explicitly recited in the claims. Additional operations can be provided before, during, and after the method 40, and some operations described can be replaced, eliminated, or reordered for additional embodiments of the method.

Some embodiments of the present disclosure provide a semiconductor device. The semiconductor device includes a substrate and a capacitor structure. The capacitor structure is disposed on the substrate. The capacitor structure includes a first electrode and a plurality of second electrodes. At least one of the plurality of second electrodes is embedded within the first electrode.

Some embodiments of the present disclosure provide a semiconductor device. The semiconductor device includes a substrate, a capacitor structure, and a logic device. The capacitor structure is disposed on a first region of the substrate. The capacitor structure includes a first electrode and a second electrode. The first electrode has an upper surface facing away from the substrate. The second electrode has an upper surface substantially aligned with the upper surface of the first electrode. The logic device includes a gate electrode. The gate electrode of the logic device is located at an elevation substantially the same as that of the first electrode of the capacitor structure with respect to the substrate.

Some embodiments of the present disclosure provide a method of manufacturing a semiconductor device. The method includes providing a substrate. The method also includes forming a first electrode on the substrate. The method further includes removing a portion of the first electrode to form a plurality of openings. In addition, the method includes forming capacitor dielectrics within the plurality of openings. The method also includes forming second electrodes on the capacitor dielectrics. The second electrodes are electrically connected to each other.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a capacitor structure disposed on the substrate, wherein the capacitor structure comprises:
a first electrode; and
a plurality of second electrodes, wherein at least one of the plurality of second electrodes is embedded within the first electrode.

2. The semiconductor device of claim 1, wherein a portion of the first electrode is disposed between the one of the plurality of second electrodes and the substrate.

3. The semiconductor device of claim 1, wherein a first thickness of the first electrode is greater than a second thickness of the one of the plurality of second electrodes.

4. The semiconductor device of claim 1, wherein the first electrode has an upper surface facing away from the substrate, and the upper surface of the first electrode is substantially aligned with an upper surface of the one of the plurality of second electrodes.

5. The semiconductor device of claim 4, wherein the first electrode has a lower surface opposite to the upper surface, and the lower surface of the first electrode has an elevation, with respect to the substrate, different from that of a lower surface of the one of the plurality of second electrodes.

6. The semiconductor device of claim 1, wherein the substrate comprises a first well region having a first conductive type, a second well region surrounded by the first well region and having a second conductive type different from the first conductive type, and a doped region over the second well region and having the first conductive type, and wherein the doped region of the substrate functions as another one of the plurality of second electrodes.

7. The semiconductor device of claim 6, wherein the substrate comprises a third well region with the second conductive type and surrounded by the second well region, and a dopant concentration of the third well region is greater than that of the second well region.

8. The semiconductor device of claim 1, further comprising:
an isolation structure within the substrate, wherein the isolation structure is disposed between the substrate and the capacitor structure.

9. The semiconductor device of claim 1, wherein the capacitor structure further comprises:
a first capacitor dielectric disposed between the first electrode and the substrate; and
a second capacitor dielectric separating the one of the plurality of second electrodes from the first electrode.

10. The semiconductor device of claim 9, wherein the first electrode has a plurality of parts physically separated from each other by the second capacitor dielectric.

11. A semiconductor device, comprising:
a substrate;
a capacitor structure disposed on a first region of the substrate, wherein the capacitor structure comprises:
a first electrode having an upper surface facing away from the substrate; and
a second electrode inset into the first electrode and having an upper surface substantially aligned with the upper surface of the first electrode; and
a logic device comprising a gate electrode, wherein the gate electrode of the logic device is located at an elevation, with respect to the substrate, substantially the same as that of the first electrode of the capacitor structure.

12. The semiconductor device of claim 11, wherein the upper surface of the second electrode of the capacitor structure has an elevation substantially the same as that of an upper surface of the gate electrode.

13. The semiconductor device of claim 11, wherein the first electrode has a lower surface opposite to the upper surface of the first electrode, and the lower surface of the first electrode has an elevation, with respect to the substrate, different from that of a lower surface of the second electrode.

14. The semiconductor device of claim 11, wherein the capacitor structure comprises a third electrode electrically connected to the second electrode, and the second electrode is located at an elevation different from that of the third electrode.

15. The semiconductor device of claim 14, wherein the substrate comprises a doped region functioning as the third electrode of the capacitor structure.

16. The semiconductor device of claim 11, further comprising:
a spacer structure sandwiching the first electrode and the second electrode.

17. The semiconductor device of claim 11, wherein the capacitor structure further comprises a capacitor dielectric separating the first electrode from the second electrode, and a portion of the first electrode is disposed between the capacitor dielectric and the substrate.

18. A method of manufacturing a semiconductor device, comprising:
providing a substrate;
forming a first electrode on the substrate;
removing a portion of the first electrode to form a plurality of openings;
forming capacitor dielectrics within the plurality of openings; and
forming second electrodes on corresponding capacitor dielectrics, wherein the second electrodes are electrically connected to each other.

19. The method of claim 18, further comprising:
planarizing the first electrode, the capacitor dielectrics, and the second electrodes.

20. The method of claim 18, further comprising:
forming a first well region within the substrate, wherein the first well region has a first conductive type;
forming a second well region surrounded by the first well region, wherein the second well region has a second conductive type different from the first conductive type;
forming a doped region over the second well region, wherein the doped region has the first conductive type; and
electrically connecting the doped region and the second electrodes.
